(19) United States
(12) Patent Application Publication
(10) Pub. No.: US 2007/0279057 A1
(43) Pub. Date: Dec. 6, 2007

(54) Method and Apparatus for Improving the Detection of Nuclear Quadrupole Resonance Signals In Coherent Noise

(76) Inventors: Taras Nikolaevitch Rudakov, Western Australia (AU); Vassili Timofeevitch Mikhaltsevitch, Western Australia (AU); John Harold Flexman, Western Australia (AU); Peter Alaric Hayes, Western Australia (AU); Warrick Paul Chisholm, Western Australia (AU)

Correspondence Address: PILLSBURY WINTHROP SHAW PITTMAN, LLP;Eric S. Cherry - Docketing Supervisor, P.O. BOX 10500, MCLEAN, VA, 22102, US

(21) Appl. No.: 10/558,393

(22) PCT Filed: May 26, 2004
(86) PCT No.: PCT/AU04/00692

§ 371 Date: Nov. 6, 2006

(30) Foreign Application Priority Data
May 26, 2003 (AU) 2003902576

(51) Int. Cl. G01R 33/44

(52) U.S. Cl. 324/314

(57) ABSTRACT

A method for exciting an NQR signal in a substance within a material that may include the substance and detecting the NQR signal in the presence of coherent noise. The method comprises irradiating the material with multiple RF pulses in the form of a complex pulse sequence containing a plurality of blocks. The basis of each block comprises a composite pulse formed by phase cycling a plurality of pulse elements. The method includes receiving a response signal after each composite pulse and processing the response signals to progressively mitigate the effect of coherent noise and to distinguish the existence of an NQR signal if present. The phase cycling comprises generating at least three pulse elements of equal duration but of differing phase to form the composite pulse. In this manner, successive blocks progressively mitigate the effect of coherent noise, and ameliorate the NQR signal if present. An apparatus for performing the method is also described.

### FIELD OF THE INVENTION

This invention relates to a method and apparatus for improving the detection of nuclear quadrupole resonance (NQR) signals emitted from a substance in the presence of coherent noise. More particularly, this invention relates to reducing the effect of coherent noise in a response signal received from a substance pursuant to irradiating the substance with radio frequency (RF) energy that causes the emission of an NQR signal from the nuclei of the substance.

Within this document the term “substance” is taken to mean a material which responds to the NQR phenomenon.

Throughout the specification, unless the context requires otherwise, the word “comprise” or variations such as “comprises” or “comprising”, will be understood to imply the inclusion of a stated integer or group of integers but not the exclusion of any other integer or group of integers.

### BACKGROUND ART

The following discussion of the background art is intended to facilitate an understanding of the present invention only. It should be appreciated that the discussion is not an acknowledgement or admission that any of the material referred to is or was part of the common general knowledge as at the priority date of the application.

Nuclear quadrupole resonance (NQR) is one of many modern research methods in physics used for the analytical detection of chemical substances in solid form. NQR is a radio frequency (RF) spectroscopy, and it is defined as a phenomenon of resonance involving the absorption or emission of RF electromagnetic energy. It is due to the dependence of a portion of the energy of electron-nuclear interactions on the mutual orientations of asymmetrically distributed charges of the atomic nucleus and the atomic shell electrons as well as those charges that are outside the atomic radius. Thus, all changes in the quadrupole coupling constants and NQR frequencies are due to their electric origin.

The nuclear electric quadrupole moment eQ interacts with the electric field gradient eq, defined by asymmetry parameter η. Therefore the nuclear quadrupole coupling constant e²Qq and the asymmetry parameter η, which contains structural information about a molecule, may be calculated from data obtained in respect of the. emitted electromagnetic energy arising from absorbed RF electromagnetic energy in a substance having nuclei that exhibit the NQR phenomena.

The main spectral parameters of interest in testing for substances containing nuclei that exhibit NQR are the transition frequencies of the nucleus and the line width Δf thereof. Besides these parameters, obtaining spin-lattice relaxation time T₁, spin-spin relaxation time T₂ and line-shape parameter T₂* (inversely proportional to Δf ) are also of great value. These additional parameters must also be taken into consideration when choosing the technique and equipment to be used for testing for the emission of NQR signals from a particular chemical substance.

In contrast to nuclear magnetic resonance (NMR) methods, NQR signal detection can be performed without a strong external DC magnetic field. This technique is known as “pure NQR”, or direct NQR detection, and has many advantages over other techniques for certain applications, such as the identification of specific compounds and remote NQR detection. For example these methods are successfully used for detecting the presence of specific substances, such as explosives and narcotics, as well as landmine detection.

The probe of a pulsed NQR detection system is a device providing interaction between the RF field of a resonant RF transmitter and a substance that is targeted for the detection of an NQR signal the material therein, as well as the RF field response from the target substance with a receiving part of the NQR detection system. Strong RF pulses, typically with the power of hundreds of watts, are used for irradiating a material that might contain the substance sought to be detected, to generate the emission of an NQR signal from the substance if present. In practical NQR devices, when detecting specific substances (for example explosives and narcotics), the RF pulse power can reach several kW.

FIG. 1 illustrates a conventional prior art system for detecting NQR signals emitted from a targeted substance.

Transmitter unit 60′ and receiver unit 50′ are connected to probe 30′ through a duplexer and matching circuit 40′ which switches probe 30′ between a transmit and a receive mode. Transmitter unit 60′ generates RF pulses and applies the pulses to probe 30′ to excite the substance. The pulses have a frequency corresponding to the resonance frequency of the quadrupolar nuclei of the substance. After the RF pulse is applied, probe 30′ will detect the emission of a response signal that may contain an NQR signal from a substance within the material, if present. The response signal is received by receiver unit 50′ and processed by control and signal processing unit 70′ to detect the presence of an NQR signal and determine the type of substance that emitted the NQR signal. The control and signal processing unit 70′ also generates all control signals and the RF carrier for the transmitter unit 60′ to generate the RF signals that are applied to the probe 30′ and a reference RF signal for use by the receiver unit 50′

Normally, detected NQR signals have low intensity. Therefore the presence of noise sources can present a serious problem, particularly for the detection of specific substances. In practical situations the investigated volume in which a targeted substance may be present, can contain objects which, when irradiated with strong RF pulses, can become sources of coherent noise (or spurious signals). These objects generate strong magneto-acoustic or piezo-electric signals.

It should be noted that transient signals (also called “ringing”) emerging in a resonant tank circuit after the RF pulses have been activated are also referred to as coherent noise, as their phase corresponds to the phase of the exciting RF pulse.

It has been discovered that multi-pulse techniques used in NMR, can also be used in NQR spectroscopy for increasing the sensitivity of detection, reducing the processing time taken in detecting a response signal, and measuring the relaxation time of a material being tested for determining the presence of a particular substance. There are many other types of pulse sequences that have been found to not only have utility in NMR spectroscopy, but also in NQR spectroscopy. These include the spin-echo, Carr-Purcell (CP), Meiboom-Gill-modified CP, spin-locking sequences (SLS) as well as other sequences.

Of greatest practical interest in the field of NQR are the pulse sequences of the steady-state free precession type (SSFP). The simplest version of this sequence is known in the art of NQR as the strong off-resonant comb (SORC) sequence. When certain requirements are complied with, these SSFP sequences can cause a stationary NQR signal to be emitted that does not decay while the sequence is operating. This method is very convenient for carrying out fast coherent accumulation (averaging) of the signal. Consequently, these particular pulse sequences are used for detecting the presence of specific substances, such as explosives and narcotics.

In NQR, it has been suggested to use two Steady-State Free Precession (SSFP) pulse sequences of the following type to eliminate coherent noise:
└θ_{0°}−τ−θ_{0°}−τ−┘ₙ
└θ_{0°}−τ−θ_{180°}−τ−┘ₙ,
where θ is a flip angle determined by the pulse length, the value of B₁ is the magnetic field of the RF pulse, and τ is a pulse repetition time.

The first sequence (also known in the art of NQR as a Strong Off Resonant Comb (SORC) sequence) is referred to as a Non-Phase-Alternated Pulse Sequence (NPAPS), and the second as a Phase Alternated Pulse Sequence (PAPS).

It has been claimed that if the receiver phase in NPAPS is set to a constant value of 180°, and in PAPS the phase is alternated with each pulse (0°-180°), this combination ensures the cancelling of coherent noise of up to 20 dB. It is not possible to achieve a better result than this as the RF pulses with phases 0° and 180° excite different signals of coherent noise, and therefore can not be completely mutually subtracted. However, despite this claim, the suggested NPAPS-PAPS combination is not practicable to use because in practice it contains an unequal number of 0° and 180° phases of RF pulses.

A further problem with the use of the preceding types of pulse sequences, is that they do not work well if the substance being detected has a relatively low resonance frequency and/or long spin-lattice relaxation time. Moreover, the aforementioned techniques achieve good elimination only in the case of comparatively short coherent noise signals. That is, if the duration of the coherent noise signals, excited by the RF pulse, is completely decayed by the time of the next pulse transmission, then the interfering noise can be largely eliminated by the suggested combination of SSFP pulse sequences. However, as soon as the duration of the coherent noise signals starts to exceed the duration of the pulse transmission period (i.e. does not fit into the “observation window”), then the level of the cancelling decreases significantly.

This is caused by the fact that part of this signal goes into the next “observation window” and is added to the coherent noise signal, created by the following RF pulse and having a different phase. It should be noted that whilst this problem is more characteristic of low frequency NQR spectroscopy, it can also be observed at higher frequencies.

Many of the shortcomings associated with the aforementioned techniques, however, can be overcome by adopting an alternative detection method. This alternative detection method involves applying two excitation blocks to excite NQR, detecting the response signals, and comparing the response signals from respective blocks. The first block is intended for the excitation of the NQR signal and coherent noise, and the second one is intended for the excitation of coherent noise only.

To ensure that the NQR signal is not measured in the second block, a certain delay is set between the two blocks, or excitation in the form of “bridging pulses” is applied. If the structures of the first and the second blocks are identical, this method ensures very efficient coherent noise elimination even in the case of low frequencies.

A shortcoming of this detection method, however, is a longer detection time. The reason for this is that the proper detection of the NQR signal is carried out by the first block only, while the second block and the delay (or “bridging pulses”) do not contribute to the NQR signal. Moreover, it has been discovered that the second block in many cases leads to subtraction of the NQR signal. The level of this subtraction depends strongly on the resonant offset. Experiments carried out by the inventors of the present invention show that at some resonant offsets the use of the second block could result in the decrease of the NQR signal intensity by 5-20%.

It has also been suggested to use an SSFP type sequence comprising composite pulses for eliminating coherent noise. The sequence consists of the repeated pair of the composite pulses comprising two elements in which the phases are shifted by 90° in relation to each other. The phase of the first element is inverted from pulse to pulse, while the phase of the second element does not change throughout the whole sequence. In reality such a sequence does not eliminate coherent noise whatever the combination of the reference phase of the receiver used. The reason for this is that each element of the composite pulse excites an independent coherent noise signal, the phase of which is determined by the phase of the respective element.

Tests undertaken of the sequence mentioned in the preceding paragraph at various frequencies from 450 kHz to 5.3 MHz and various sources of coherent noise (including magneto-acoustic and piezo-electric signals) showed that the maximum damping of the coherent noise achieved using this technique does not exceed 2 dB. This is not sufficient for any application of the NQR phenomena to a scanning device that has practical utility in the real world.

### DISCLOSURE OF THE INVENTION

The purpose of this invention is to provide for a high probability of NQR signal detection in the presence of coherent noise (or spurious signals).

Moreover, it is an object of this invention to significantly reduce the effect of coherent noise in the response signal in NQR detection without increasing considerably the processing time required to detect an NQR signal being targeted using a specific sequence of composite RF pulses.

In accordance with one aspect of the present invention, there is provided a method for exciting an NQR signal in a substance within a material that may include the substance, the method comprising:
irradiating a material with multiple RF pulses in the form of a complex pulse sequence containing a plurality of blocks, the basis of each block comprising a composite pulse formed by phase cycling a plurality of pulse elements;
receiving a response signal after each composite pulse; and
processing the response signals to progressively mitigate the effect of coherent noise and to distinguish the existence of an NQR signal if present;
   wherein the phase cycling comprises generating at least three pulse elements of equal duration but of differing phase to form the composite pulse.

Preferably, each block contains the same number of composite pulses, the structure of the composite pulses in each block being different and arranged so that after an appropriate signal processing of the detected response signals, the NQR signals are accumulated and the coherent noise is cancelled.

Preferably, the complex pulse sequence is of the SSFP type.

Alternatively, the complex pulse sequence may be of the SLS type.

Preferably, the method involves the following steps:
(a) applying excitation to a tank circuit of a probe to excite NQR in a substance if present in the material;
(b) detecting response signals induced in the probe;
(c) processing said response signals to distinguish the NQR signal from coherent noise.

According to another aspect of the present invention, there is provided a method for detecting NQR signals in a material in the presence of coherent noise, comprising:
applying a specific sequence of RF composite pulses, comprising a plurality of blocks with the same number of RF composite pulses, but each RF composite pulse having pulse elements therein of differing phase;
detecting response signals, which contain NQR signals together with the coherent noise; and
signal processing said response signals to distinguish the NQR signal from the coherent noise.

Preferably, the sequence of RF composite pulses are formed into a pulse sequence of the SSFP type.

Alternatively, the sequence of RF composite pulses may be formed into a pulse sequence of the SLS type.

In accordance with another aspect of the invention, there is provided an apparatus for exciting NQR signals from a substance within a material that may contain the substance and detecting the NQR signals, comprising:

a transmitter, a receiving system and a probe;

the probe comprising a tank circuit, including a coil where the material is placed;

the transmitter being adapted to generate a multi-pulse sequence comprising composite RF pulses and applying said multi-pulse sequence to the tank circuit, where an RF magnetic field is generated within the coil irradiating the material; and

the receiving system being adapted to receive a response signal induced upon said coil in response to said RF pulses, and to process said response signal to distinguish an NQR signal, if present, from coherent noise;

wherein said multi-phase pulse sequence is based on using a complex pulse sequence containing at least four blocks.

Preferably, the complex pulse sequence is of the SSFP type.

Alternatively, the complex pulse sequence may be of the SLS type.

In this manner the magnetic field, generated by the RF pulses applied to the coil, interacts with the material and leads to the excitation of an NQR signal from the substance if present. If there is a source of coherent noise in the coil, then after the RF pulse stops, resonance and coherent noise signals exist together within the coil. Signals from the output of the tank circuit are amplified and detected by the receiving system, after which special signal processing occurs to distinguish the NQR signal.

### BRIEF DESCRIPTION OF THE DRAWINGS

FIG. 1 (prior art) is a block diagram of a conventional apparatus for detecting a resonance signal in the material.

FIG. 2 is a graph of a composite pulse t_{W} made up of three pulses with equal duration of t and phases Ph₁, Ph₂, Ph₃ respectively, that is used in each of the embodiments of the invention.

FIG. 3 is a timing diagram of an SSFP type pulse sequence with composite pulses, according to a first embodiment of the present invention.

FIG. 4 shows two graphs of the resonance responses of a typical NQR substance that are received after applying different blocks of the pulse sequence; whereby:

FIG. 4A show the resonance response received after using only the first block of the sequence; and

FIG. 4B shows the resonance response received after using the whole sequence;

respectively, according to the first embodiment of the present invention.

FIG. 5 is a timing diagram of a pulse sequence with preparation pulses and composite pulses, according to a third embodiment of the present invention.

FIG. 6 is a timing diagram of a pulse sequence with preparation pulses, composite pulses and a delay between blocks, according to a seventh embodiment of the present invention.

FIG. 7 is a block diagram illustrating an NQR apparatus for detecting a nuclear quadrupole resonance signal in a material, according to the first embodiment of the present invention.

FIG. 8 shows two graphs of the resonance response signals from nickel-plated connectors, received after using two different types of pulse sequences; whereby:

FIG. 8A shows the resonance response signal received after using a conventional SSFP pulse sequence; and

FIG. 8B shows the resonance response signal received after using a pulse sequence according to the seventh embodiment of the present invention.

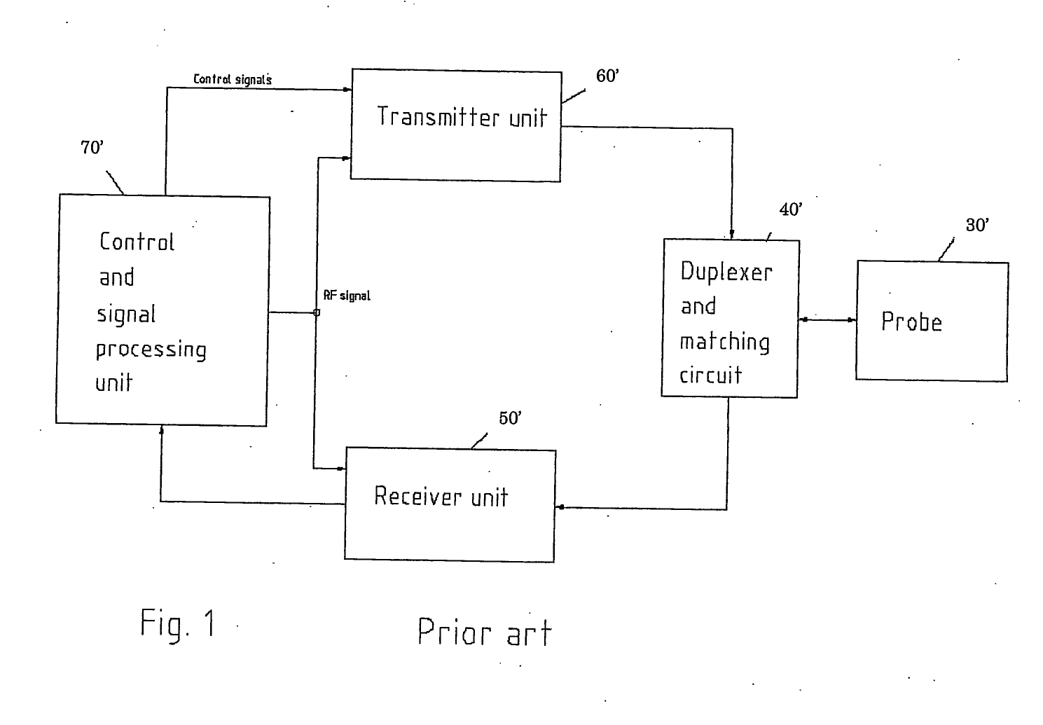

### BEST MODE(S) FOR CARRYING OUT THE INVENTION

The best mode for carrying out the invention will now be described by way of various specific embodiments with reference to the accompanying drawings. The embodiments are directed towards different methods and apparatuses for detecting the presence of a targeted substance that may be present within a material under test using an improved NQR detection technique that substantially eliminates or at least mitigates the effect of coherent noise while preserving a high signal-to-noise ratio (SNR), without any significant increase in the detection time.

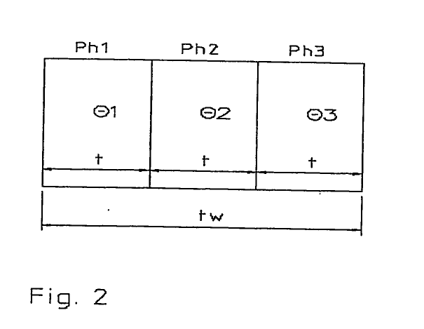

The detection technique used for eliminating coherent noise (spurious signals) described in the present embodiments is based on the use of composite pulses. This technique involves using a composite pulse consisting of three elements of equal duration but of differing phase. The structure of such a composite pulse is shown in FIG. 2 where the composite pulse t_{W} comprises three pulse elements θ1, θ2 and θ3 of equal duration t, and phases Ph1, Ph2 and Ph3, respectively.

It has been discovered, pursuant to the present invention, that a composite pulse t_{W} involving this type of phase cycling, allows for the effective detection of an NQR signal and the cancellation of coherent noise.

Further, it has been discovered that these composite pulses t_{W} can be formed into multi-pulse sequences of SSFP type or Pulsed Spin Locking (PSL) type, which permits detection of NQR signals with high SNR, practically of the same strength as those signals produced by ordinary SSFP or PSL sequences.

This composite pulse t_{W} constitutes the basis of the pulse sequences that will now be described in detail with respect to the specific embodiments of the present invention.

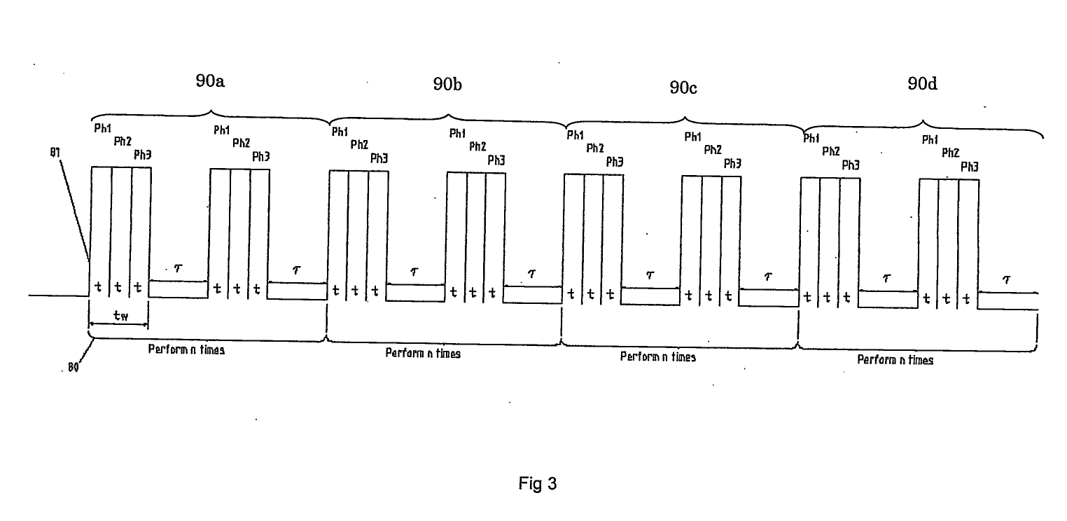

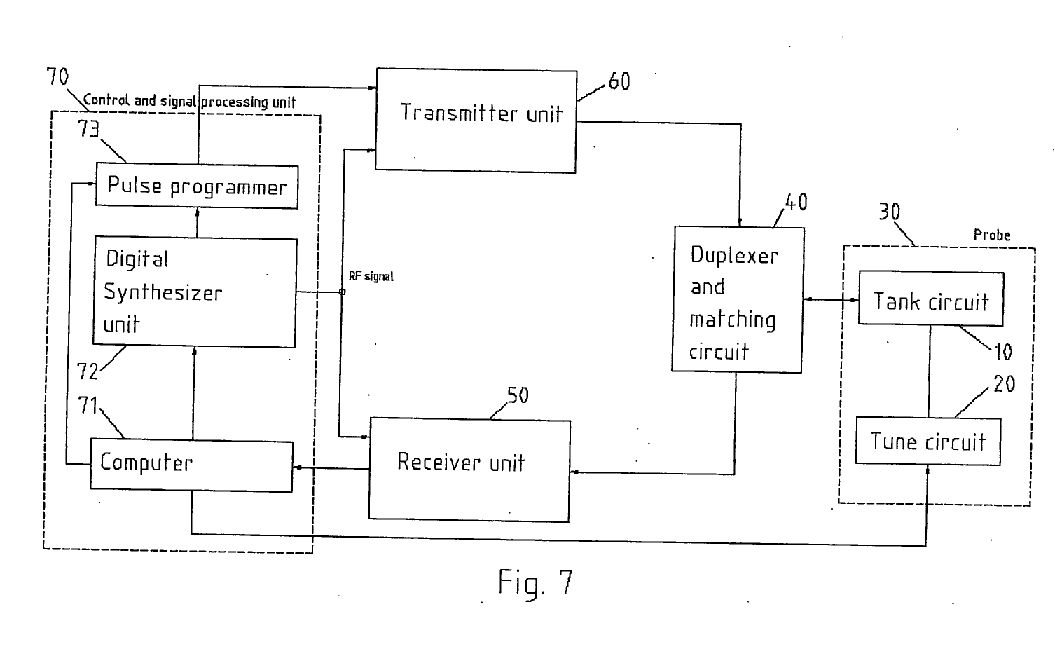

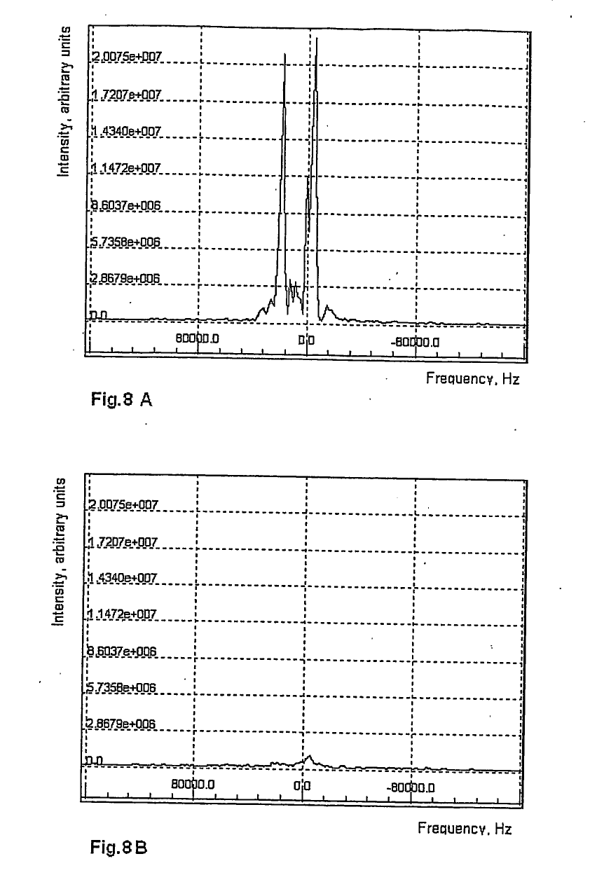

The first embodiment of the present invention involves the use of a pulse sequence as illustrated in FIG. 3 as generated by an NQR detection apparatus schematically illustrated in FIG. 7 of the drawings.

Firstly describing the NQR apparatus 11 in detail, probe 30 is connected to receiver unit 50 and conventional transmitter unit 60 via duplexer and matching circuit 40. Probe 30 includes tank circuit 10 and tune circuit 20. Tank circuit 10 is tuned to a frequency of interest with tune circuit 20.

Duplexer and matching circuit 40 is a circuit which switches tank circuit 10 between the transmit and receive mode as well as matching receiver unit 50 and transmitter unit 60 to tank circuit 10. Transmitter unit 60 generates RF pulses and transfers the pulses to tank circuit 10. These RF pulses can excite NQR signals in the particular substance under investigation if it is present in the material under test which is located in probe 30. The signals received from the material by the probe in response to the RF pulses that irradiate the material are amplified and detected by receiver unit 50 and then delivered for further mathematical processing into a computer 71, which is part of control and signal processing unit 70.

Control and signal processing unit 70 consists of a computer 71, an RF signal source in the form of digital synthesiser unit 72 and pulse programmer 73 (for producing control signals). Digital synthesiser unit 72 generates an RF signal, which from its first output is transmitted to one of the inputs of transmitter unit 60 for further formation of the RF carrier of RF pulses and to one of the inputs of receiver unit 50 as the reference frequency. Pulse programmer 73 generates control signals, which are transferred to another input of transmitter unit 60 to prescribe parameters for RF pulses that are generated. Pulse programmer 73 is controlled with computer 71, one of the outputs of which is connected with the second input of programmer 73. Computer 71 also generates control signals for tune circuit 20.

In this embodiment, the pulse sequence generated by the NQR apparatus 11 for the purposes of irradiating the material disposed within a target volume with an RF magnetic field signal, comprises four blocks 90 of excitation RF pulses. Each block comprises an SSFP pulse sequence 80 of composite pulses 81. Each composite pulse 81 of the sequence is of the type of composite pulse t_{W} described above, consisting of three elements of equal duration t and each block involves the generation of a pair of composite pulses 81 and cycled through n times, before the next block is commenced. Although the present embodiment describes the generation of a pair of composite pulses 81 for each cycle, the number of composite pulses generated in each cycle is arbitrary, and can comprise a single composite pulse or any convenient number of composite pulses.

The resonance response signals from the four blocks are detected and processed in appropriate fashion such that the NQR signals are distinguished from the coherent noise.

A single block comprising cycling of a single composite pulse may be written as:
[θ_{Ph1}θ_{Ph2}θ_{Ph3}−τ−]ₙ
where θ_{Ph} indicates a pulse flip angle θ and the particular phase of the RF carrier Ph, τ is the time between pulses, and n is the number of times that the pulse sequence is cycled through.

Consequently, the complete pulse sequence using a single composite pulse as the basis for each block (as opposed to a pair of composite pulses shown in FIG. 3), may be written as:

$${[ {θ}_{Ph 1} {θ}_{Ph 2} {θ}_{Ph 3} - τ - ]}_{n}^{Block 1} - {[ {θ}_{Ph 1} {θ}_{Ph 2} {θ}_{Ph 3} - τ - ]}_{n}^{Block 2} - {[ {θ}_{Ph 1} {θ}_{Ph 2} {θ}_{Ph 3} - τ - ]}_{n}^{Block 3} - {[ {θ}_{Ph 1} {θ}_{Ph 2} {θ}_{Ph 3} - τ - ]}_{n}^{Block 4}$$

The phase arrangement for the composite pulses of each block 90 of this sequence is shown in the table below:

Phase settings

| Phase | Block1 | Block2 | Block3 | Block4 |
|---|---|---|---|---|
| Ph1 | 270° | 270° | 90° | 90° |
| Ph2 | 90° | 90° | 90° | 90° |
| Ph3 | 0° | 180° | 180° | 0° |
| Receiver | 0° | 180° | 0° | 180° |

After each composite pulse within the blocks is transmitted and the RF signal generated to irradiate the material, the response signal from the material is received by the probe and then sampled via an analogue-to-digital converter (ADC), where it becomes a digital signal. Over the duration of the pulse sequence, each signal is processed identically and added together digitally to form the final accumulated signal. Through the reversal of the receiver phase this accumulated signal contains mostly NQR signal and the coherent noise is either fully or partially cancelled. This signal is then processed through a fourier transform, as per standard signal processing techniques, to reveal frequency information.

It should be noted that the pulse sequence described above, is peculiar and advantageous in comparison with sequences suggested previously as a consequence of the fact that all blocks contribute to the detection of the NQR signal. This produces a significant improvement to the SNR. In some sequences suggested in the prior art, only the first block is intended to detect the NQR signal, while the second block of the same duration does not contribute to the input of the NQR signal, rather it is concerned solely with cancelling the noise provided by the first block. In this sense, the contribution to noise of the second block itself in these sequences is not taken into account and consequently increases the general noise level.

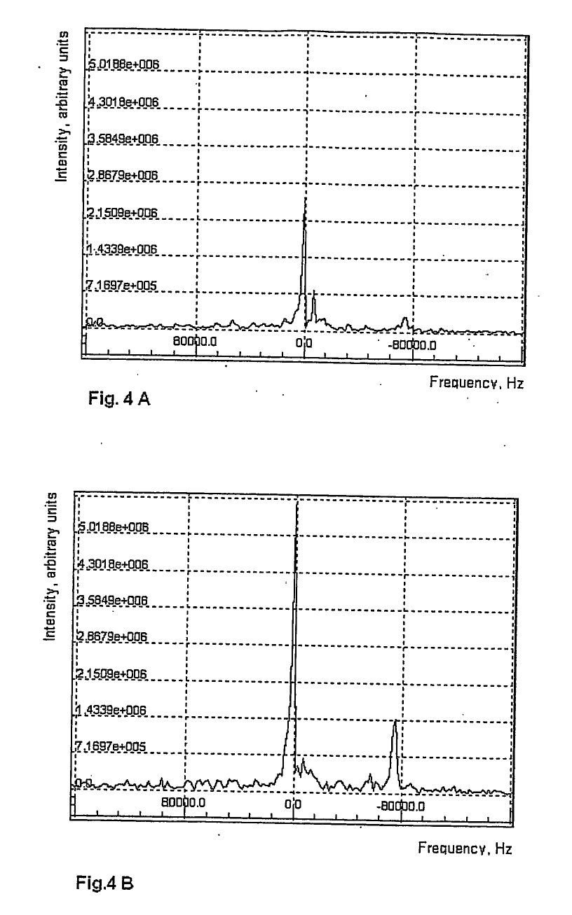

FIG. 4 illustrates the effect of increasing NQR signal intensity when using the pulse sequence of the present embodiment. In FIG. 4a, the NQR signal can be seen as detected from a ¹⁴N nuclei in KNO₃ at room temperature when only the first block of the pulse sequence was used. In contrast, in FIG. 4b the NQR signal can be seen as detected after using the whole pulse sequence, in accordance with the present embodiment.

It can easily be observed that when using the pulse sequence of the present embodiment, the NQR signals are detected in all blocks, which leads to increasing the intensity of the resulting NQR signal. The biggest contributor to the intensity of the resulting signal is (at least 30%) still made by the first block.

The second embodiment is substantially similar to the first embodiment, whereby the pulse sequence has the same structure as the pulse sequence of the preceding embodiment, but differs from it only by the order of the phase settings in composite pulses 81.

The phase arrangement for this variant is shown in the following table:

Phase settings

| Phase | Block1 | Block2 | Block3 | Block4 |
|---|---|---|---|---|
| Ph1 | 180° | 180° | 0° | 0° |
| Ph2 | 0° | 0° | 0° | 0° |
| Ph3 | 0° | 180° | 180° | 0° |
| Receiver | 0° | 180° | 0° | 180° |

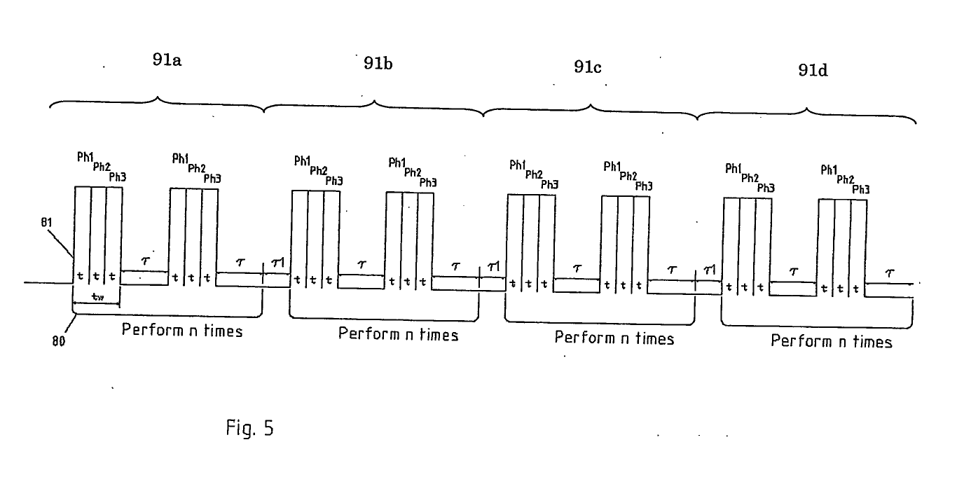

The third embodiment is substantially similar to the first embodiment, except that it involves generating a pulse sequence as shown in FIG. 5 of the drawings. This pulse sequence only differs from that of the first embodiment by the use of a set delay τ₁ 83 between blocks 91.

The pulse sequence using a single composite pulse to constitute the basis of a block (as opposed to a pair of composite pulses) utilising the set delay τ₁ of the present embodiment, may be written as:

$${[ {θ}_{Ph 1} {θ}_{Ph 2} {θ}_{Ph 3} - τ - ]}_{n}^{Block 1} - {τ}_{1} - {[ {θ}_{Ph 1} {θ}_{Ph 2} {θ}_{Ph 3} - τ - ]}_{n}^{Block 2} - {τ}_{1} - {[ {θ}_{Ph 1} {θ}_{Ph 2} {θ}_{Ph 3} - τ - ]}_{n}^{Block 3} - {τ}_{1} - {[ {θ}_{Ph 1} {θ}_{Ph 2} {θ}_{Ph 3} - τ - ]}_{n}^{Block 4}$$

Thus each block commences after a set delay τ₁ and the composite pulses are cycled through n times, to complete the pulse sequence of one block before the pulse sequence of the next block commences. The pulse sequence of the next block will not commence, however, until after another set delay τ₁ is provided.

The use of the delay τ₁ 83 between the blocks can help to increase the SNR when detecting the NQR signals. If the value τ₁≧T₁ (where T₁ is the spin-lattice relaxation time) then the spin-system to a considerable extent has sufficient time for relaxation before the next block begins. This leads to an increase of the intensity of the NQR signal detected in this block.

The fourth embodiment is a variant of the third embodiment of the pulse sequence, differing only by the phase settings of the composite pulses. The phase settings of the pulses are the same as in the second embodiment, as opposed to those of the pulse sequence of the first embodiment.

The fifth embodiment is a variant-of the third and fourth embodiments.

As described in relation to the third embodiment, the use of the delay τ₁ 83 between the blocks can help to increase the SNR when detecting the NQR signals. However, this is only practicable where the delay τ₁ is greater than or equal to the spin-lattice relaxation time T₁, where the spin-system has sufficient time for relaxation before the next block begins. In the case of a long T₁ relaxation time this method causes a considerable increase in the detection time. Therefore for practical purposes using the delay τ₁≧T₁ is most expedient when detecting substances with comparatively short values of T₁ (for example RDX). For substances with long T₁ relaxation times (for example PETN, TNT, KNO₃ or NH₄NO₃) this delay is not required.

Accordingly, in the present embodiment, the computer 71 is particularly programmed to switch the pulse programmer 73 between different pulse formation programs, depending upon the substance being detected. Moreover, in the case of detecting a substance such as RDX, having a relatively short spin-lattice relaxation time T₁, a pulse sequence formation of the type described in the first or second embodiments is used. In the case of detecting a substance such as PETN, TNT, KNO₃ or NH₄NO₃, a pulse sequence formation of the type described in the third or fourth embodiments is used.

The sixth embodiment is substantially the same as each of the previous embodiments, except that it uses a preparation pulse in the pulse sequences included in the four blocks. The preparation pulse can be used either in a single block, in several blocks, or in all of the blocks of the pulse sequence.

The preparation pulses in this embodiment occur in time at the commencement of the particular block in which they are used. The preparation pulse commences after an initial lead time τ₁ (same as the set delay described in the third embodiment) from the commencement of the block, is of a time duration t, and thereafter a delay time interval τ₀ is provided before the commencement of the composite pulse pair, which is then cycled through n times to before the end of the block.

In the present embodiment, the delay time interval τ₀ is constant, although the time duration t may vary, from block to block in which the preparation pulses occur.

Using preparation pulses in this manner can bring about an additional increase in the intensity of the NQR signals. It is of particular importance when the NQR signals are detected in substances in which the ratio of T₁/T₂ (T₁ being the spin-lattice relaxation time, and T₂ being the spin-spin relaxation time) is greater than about five.

It has also been discovered, pursuant to the present invention, that the use of preparation pulses changes the dependence between the intensity of NQR signals in the observation windows and the resonance offset. This dependence is quite considerable when the material is scanned for certain specific substances, as the NQR frequency is also temperature dependent. In order to improve the off resonance performance, the parameters of the preparation pulse in the blocks are arranged so that all blocks would generate response signals whose variations with frequency would in combination be less than for the response signals from each block separately.

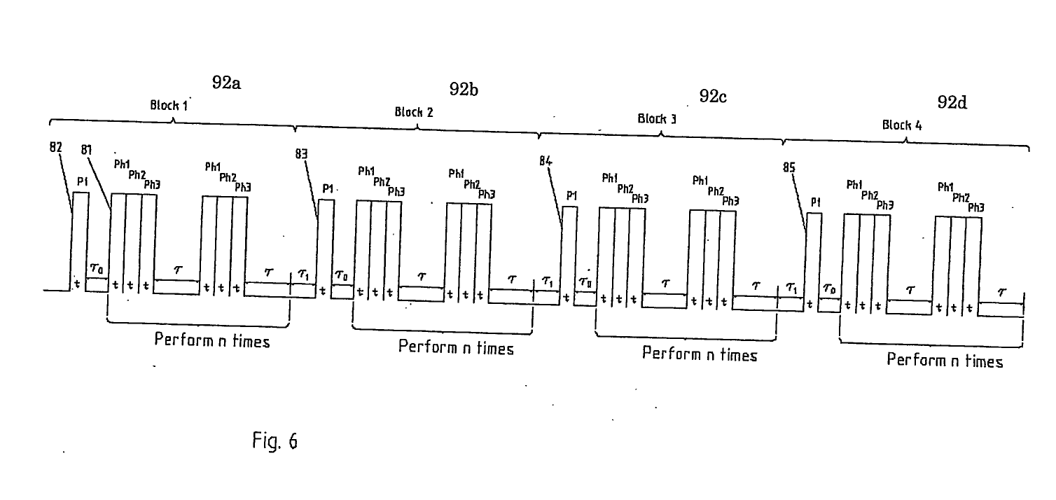

The seventh embodiment is substantially the same as the sixth embodiment, but is directed towards a more specific embodiment of the invention, whereby a pulse sequence of the type shown in FIG. 6 of the drawings is adopted.

As shown, the preparation pulses 82, 83, 84 and 85 are provided in each block 92. Although the duration of each preparation pulse may be different, in the present embodiment their duration is of equal time t. Furthermore, although the phases of the preparation pulses 82, 83, 84 and 85 can be the same, in the present embodiment they alternate in each block. Further still, the phases of the preparation pulses differ from the phases of the respective composite pulses by the value of 90°.

Consequently, the pulse sequence of the present embodiment may be written as:

$${θ}_{P 1} - {τ}_{0} - {[ {θ}_{Ph 1} {θ}_{Ph 2} {θ}_{Ph 3} - τ - ]}_{n}^{Block 1} - {τ}_{1} - {θ}_{P 2} - {τ}_{0} - {[ {θ}_{Ph 1} {θ}_{Ph 2} {θ}_{Ph 3} - τ - ]}_{n}^{Block 2} - {τ}_{1} - {θ}_{P 3} - {τ}_{0} - {[ {θ}_{Ph 1} {θ}_{Ph 2} {θ}_{Ph 3} - τ - ]}_{n}^{Block 3} - {τ}_{1} - {θ}_{P 4} - {τ}_{0} - {[ {θ}_{Ph 1} {θ}_{Ph 2} {θ}_{Ph 3} - τ - ]}_{n}^{Block 4}$$

The eighth embodiment is a variant of the sixth and seventh embodiments, whereby the pulse sequence adopted in this embodiment has different delay time intervals τ₀ in different blocks.

The ninth embodiment is substantially the same as the sixth embodiment, except that the intervals between pulses. (τ) are set so that the sequence acts predominantly as a SLS type.

According to each of the above embodiments of the present invention the use of a combination sequence containing at least four blocks, each of them containing the same number of composite pulses with corresponding phase settings results in a considerable decrease of the size of the coherent noise in the resulting signal and thus increases the efficiency of detecting target substances. Consequently, the NQR signal is able to be detected during the implementation of the whole pulse sequence, which increases the SNR and shortens the detection time.

It should be appreciated that the scope of the present invention is not limited to the particular embodiments described herein, and that other embodiments of the invention may be envisaged without departing from the spirit of the invention.

1. A method for exciting an NQR signal in a substance within a material that may include the substance, the method comprising:
irradiating a material with multiple RF pulses in the form of a complex pulse sequence containing a plurality of blocks, the basis of each block comprising a composite pulse formed by phase cycling a plurality of pulse elements;
receiving a response signal after each composite pulse; and
processing the response signals to progressively mitigate the effect of coherent noise and to distinguish the existence of an NQR signal if present;
wherein the phase cycling comprises generating at least three pulse elements of equal duration but of differing phase to form the composite pulse.

2. A method as claimed in claim 1, including cycling the composite pulse or a plurality of composite pulses a prescribed time interval apart and a prescribed number of times to complete the pulse sequence of a block, wherein the cycling is the same for each block, but where the phase arrangement of each pulse element constituting the composite pulse within each block is different from block to block so that after an appropriate signal processing of the detected response signals, the NQR signals are accumulated and the coherent noise is cancelled.

3. A method as claimed in claim 1, wherein the plurality of blocks number at least four.

4. A method as claimed in claim 3, wherein the phase arrangement of the three phase elements of the composite pulses and the receiver phase is:
within the first block: 270°, 90°, 0°, and the receiver phase is 0°;
within the second block: 270°, 90°, 180°, and the receiver phase is 180°;
within the third block; 90°, 90°, 180°, and the receiver phase is 0°; and
within the fourth block: 90°, 90°, 0°, and the receiver phase is 180°.

5. A method as claimed in claim 3, wherein the phase arrangement of the three phase elements of-composite pulses and the receiver phase is:
within the first block: 180°, 0°, 0°, and the receiver phase is 0°;
within the second block: 180°, 0°, 180°, and the receiver phase is 180°;
within the third block: 0°, 0°, 180°, and the receiver phase is 0°; and within the fourth block: 0°, 0°, 0°, and the receiver phase is 180°.

6. A method as claimed in claim 1, including adding a set delay between successive blocks, the set delay being greater than or equal to the spin-lattice relaxation time of the substance being detected.

7. A method as claimed in claim 6, including selectively adding or omitting the set delay between blocks, depending upon the relative length of the spin-lattice relaxation time of the substance being detected, so that the set delay is used for detecting substances having a relatively short spin-lattice relaxation time, but is omitted for detecting substances having a relatively long spin-lattice relaxation time.

8. A method as claimed in claim 6, wherein the set delay is used for detecting RDX.

9. A method as claimed in claim 1, including transmitting a preparation pulse at the commencement of one or more blocks in the complex pulse sequence, before phase cycling the composite pulse(s) of the particular block.

10. A method as claimed in claim 9, including adding a set delay between successive blocks, the set delay being greater than or equal to the spin-lattice relaxation time of the substance being detected wherein the preparation pulse is not transmitted until after the set delay, where the preparation pulse occurs within a block.

11. A method as claimed in claim 9, wherein a delay time interval is provided after transmitting the preparation pulse and before commencement of the composite pulse within a block, said delay time interval being constant in each block where the preparation pulse is transmitted.

12. A method as claimed in claim 9, wherein a delay time interval is provided after transmitting the preparation pulse and before commencement of the composite pulse, said delay time interval being different in the block where a preparation pulse is transmitted, from the delay time interval provided in a different block where another preparation pulse is transmitted.

13. A method as claimed in claim 9, wherein the preparation pulse is of constant duration in each block where the preparation pulse is transmitted.

14. A method as claimed in claim 9, wherein the preparation pulse is of varying duration in different blocks where the preparation pulse is transmitted.

15. A method as claimed in claim 9, wherein preparation pulses are transmitted where the ratio of the spin-lattice relaxation time to the spin-spin relaxation time of the substance being detected is greater than about five.

16. A method as claimed in claim 9, wherein the parameters of the transmitted preparation pulse(s) are arranged so that all blocks generate response signals whose variations with frequency would, in combination, be less than for the response signals from each block separately.

17. A method as claimed in claim 9, wherein the phase of each successive preparation pulse occurring in different successive blocks alternates.

18. A method as claimed in claim 9, wherein the phase of the preparation pulse within a block, differs from the phase of the composite pulse(s) within the same block by 90°.

19. A method as claimed in claim 1, wherein the complex pulse sequence is of the SSFP type.

20. A method as claimed in claim 1, wherein the complex pulse sequence is of the SLS type.

21. A method as claimed in claim 1, including:
(a) applying excitation to a tank circuit of a probe to excite NQR in a substance if present in the material;
(b) detecting response signals induced in the probe;
(c) processing said response signals to distinguish the NQR signal from coherent noise.

22. A method for detecting NQR signals in a material in the presence of coherent noise, comprising:
applying a specific sequence of RF. composite pulses, comprising a plurality of blocks with the same number of RF composite pulses, but each RE composite pulse having pulse elements therein of differing phase;
detecting response signals, which contain NQR signals together with the coherent noise; and
signal processing said response signals to distinguish the NQR signal from the coherent noise.

23. A method as claimed in claim 22, wherein the basis of each block comprises a composite pulse formed by phase cycling at least three pulse elements of equal duration but of differing phase to form the composite pulse.

24. An apparatus for exciting NQR signals from a substance that may be present in a material and detecting the NQR signals if the substance is present in the material, the apparatus comprising:
a transmitter, a receiver and a probe;
the probe comprising a tank circuit, including a coil where the material is placed;
the transmitter being adapted to generate a composite pulse sequence comprising a plurality of pulse elements and applying said composite pulse sequence to the tank circuit, where multiple RF pulses are generated within the coil to irradiate the material; and
the receiver being adapted to receive a response signal induced upon said coil in response to said RF pulses, and to process said response signal to distinguish an NQR signal, if present, from coherent noise;
wherein said composite pulse sequence forms a plurality of blocks that progressively counter the effect of coherent noise and accumulate an NQR signal if present.

25. An apparatus as claimed in claim 24, wherein the basis of each block comprises a composite pulse formed by phase cycling at least three pulse elements of equal duration but of differing phase to form the composite pulse.

26-28. (canceled)

29. An apparatus for exciting NQR signals from a substance that may be present in a material and detecting the NQR signals if the substance is present in the material, the apparatus comprising:
a probe comprising a tank circuit, including a coil where the material is placed;
means for generating a composite pulse sequence comprising a plurality of pulse elements and for applying said composite pulse sequence to the tank circuit, where multiple RF pulses are generated within the coil to irradiate the material; and
means for receiving a response signal induced upon said coil in response to said RF pulses, and for processing said response signal to distinguish an NQR signal, if present, from coherent noise;
wherein said composite pulse sequence forms a plurality of blocks that progressively counter the effect of coherent noise and accumulate an NQR signal if present.

30. An apparatus as claimed in claim 29, wherein the basis of each block comprises a composite pulse formed by phase cycling at least three pulse elements of equal duration but of differing phase to form the composite pulse.

31. A signal for irradiating a material to excite NQR signals from a substance that may be present within the material, the signal comprising a composite pulse sequence comprising a plurality of pulse elements forming a plurality of blocks that progressively counter the effect of coherent noise and accumulate an NQR signal if present.

32. A signal for irradiating a material to excite NQR signals from a substance that may be present within the material the signal comprising a complex pulse sequence containing a plurality of blocks, the basis of each block comprising a composite pulse formed by phase cycling a plurality of pulse elements, wherein the phase cycling comprises generating at least three pulse elements of equal duration but of differing phase. to form the composite pulse to progressively mitigate the effect of coherent noise and to distinguish the existence of an NQR signal if present.

33. A signal as claimed in claim 32, wherein the composite pulse or a plurality of composite pulses are cycled a prescribed time interval apart and a prescribed number of times to complete the pulse sequence of a block, wherein the cycling is the same for each block, but where the phase arrangement of each pulse element constituting the composite pulse within each block is different from block to block so that the NQR signals arc accumulated and the coherent noise is cancelled.

34. A signal as claimed in claim 32, wherein the plurality of blocks number at least four.

35. A signal as claimed in claim 32, comprising a set delay between successive blocks, the set delay being greater than or equal to the spin-lattice relaxation time of the substance being detected.

36. A signal as claimed in claim 35, wherein the set delay is used for detecting RDX.

37. A signal as claimed in claim 32, comprising a preparation pulse at the commencement of one or more blocks in the complex pulse sequence, before phase cycling the composite pulse(s) of the particular block.

38. A signal as claimed in claim 37, comprising a set delay between successive blocks, the set delay being greater than or equal to the spin-lattice relaxation time of the substance being detected wherein the preparation pulse is not transmitted until after the set delay, where the preparation pulse occurs within a block.

39. A signal as claimed in claim 37, comprising a delay time interval provided after the preparation pulse and before commencement of the composite pulse within a block, said delay time interval being constant in each block where there is a preparation pulse.

40. A signal as claimed in claim 37, comprising a delay time interval provided after the preparation pulse and before commencement of the composite pulse, said delay time interval being different in the block where there is a preparation pulse, from the delay time interval provided in a different block where there is another preparation pulse.

41. A signal as claimed in claim 37, wherein the preparation pulse is of constant duration in each block where there is a preparation pulse.

42. A signal as claimed in claim 37, wherein the preparation pulse is of varying duration in different blocks where there is a preparation pulse.

43. A signal as claimed in claim 37, comprising preparation pulses where the ratio of the spin-lattice relaxation time to the spin-spin relaxation time of the substance being detected is greater than about five.

44. A signal as claimed in claim 37, wherein the parameters of the preparation pulse(s) are arranged so that all blocks generate response signals whose variations with frequency would, in combination, be less than for the response signals from each block separately.

45. A signal as claimed in claim 37, wherein the phase of each successive preparation pulse occurring in different successive blocks alternates.

46. A signal as claimed in claim 37, wherein the phase of the preparation pulse within a block, differs from the phase of the composite pulse(s) within the same block by 90°.

47. A signal as claimed in claim 32, wherein the complex pulse sequence is of the SSFP type.

48. A signal as claimed in claim 32, wherein the complex pulse sequence is of the SLS type.
